(19) United States
(12) Patent Application Publication
(10) Pub. No.: US 2025/0063774 A1
(43) Pub. Date: Feb. 20, 2025

(54) SIC TRENCH DEVICES HAVING N-TYPE GATE OXIDE SHIELD ZONES

(71) Applicant: Nami MOS CO., LTD., New Taipei City (TW)

(72) Inventors: FU-YUAN HSIEH, New Taipei City (TW); LIN XU, SHANGHAI (CN)

(73) Assignees: Nami MOS CO., LTD., New Taipei City (TW); Shenzhen Puolop Electronics Co., Ltd, Shenzhen (CN)

(21) Appl. No.: 18/234,083

(22) Filed: Aug. 15, 2023

(51) Int. Cl. H01L 29/06; H01L 29/10; H01L 29/16; H01L 29/40; H01L 29/78

(52) U.S. Cl. CPC H01L 29/0634; H01L 29/1095; H01L 29/1608; H01L 29/407; H01L 29/7813

(57) ABSTRACT

An improved SiC trench MOSFET having N-type and P-type shield zones for gate oxide electric-field reduction is disclosed. The N-type shield zones are formed below a gate electrode and the P-type shield zones adjoin lower surfaces of the body regions. The device further comprises a current spreading region surrounding at least sidewalls of the gate trenches for on-resistance reduction.

### FIELD OF THE INVENTION

This invention relates generally to semiconductor devices, and more particularly, to a silicon carbide (SiC) trench Metal Oxide Semiconductor Field Effect Transistor (MOSFET) having an N-shield (Ns) zone for gate oxide protection. The device further comprises a current spreading region surrounding gate trenches below body regions, to achieve a lower electric-field strength at the gate oxide, lower on-resistance, smaller gate-drain charge (Qgd) and lower switching loss.

### BACKGROUND OF THE INVENTION

Because of the physical properties of SiC, SiC-MOSFETs can achieve a higher breakdown voltage, lower on-resistance and higher switching speed than Si-MOSFETs. However, SiC-MOSFETs have a higher electric-field strength at the gate oxide than Si-MOSFETs because of the poor interface state between SiC and the gate oxide requiring higher Vgs to fully turn on device channel. E.g., for Si device, Vgs=10V can fully turn on the Si device channel but for SiC requires Vgs=18V. The higher Vgs causes higher electric filed strength at gate oxide resulting in reliability issue.

Another issue is that a gate oxide grown at trench bottom of the SiC device is much thinner than that at trench sidewalls (about 3-5 times thinner) as shown in FIG. 1, not only causing higher Qgd but also making much higher gate oxide electric-field strength at trench bottom. The device structure described in FIG. 1 is similar to a conventional Si trench MOSFET except for the N+ SiC substrate 101 and the SiC epitaxial layer 102, and the device has n+ source regions 111 and P body regions 110. Besides, a gate trench 103 filled up with a gate electrode 105 is formed in the SiC epitaxial layer 102 having a thermally grown gate oxide 109 on trench sidewalls and another gate oxide 106 on trench bottom. The thickness of the gate oxide 106 is less than a thickness of the gate oxide 109 as a result of oxidation rate of trench bottom on Si plane is the lowest in crystal plane of SiC.

FIGS. 2A-2C show three embodiments of a prior art (U.S. Pat. No. 9,923,066 B2) having a shield zone 103-2 wrapping around the right-hand sidewall of a gate trench 14 and partial trench bottom region 14-1 for gate oxide protection. However, the embodiments scarify 50% channel region in a drift region at expense of the shield zone 103-2 installation resulting in high specific on-resistance.

Therefore, there is still a need in the art of the SiC semiconductor device design and fabrication to provide a novel cell structure, device configuration and manufacturing process that would resolve these difficulties and design limitations, making SiC trench devices have lower electric-field strength at the gate oxide, achieve lower on-resistance, smaller Qgd and lower switching loss.

### SUMMARY OF THE INVENTION

The present invention discloses a SiC trench MOSFET having an N-type shield (Ns) zone disposed below a gate electrode and a P-type shield (Ps) zone adjoining a body region for gate oxide electric-field reduction. The device further comprises a current spreading (CS) region surrounding the gate electrode below a body region to further avoid the pinching off effect between the two adjacent P-shield (Ps) regions for on-resistance reduction, wherein doping concentrations of the Ns zone and CS region are higher than a doping concentration of the epitaxial layer (Nepi). It should be capable of achieving a smaller Qgd and specific on-resistance as well as further reduction in switching loss compared to a conventional SiC MOSFET and the prior arts.

According to one aspect, the invention features a SiC power device comprising a plurality of unit cells with each unit cell in an active area comprising: an epitaxial layer of a first conductivity type on a substrate; at least one gate trench surrounded by a source region of the first conductivity type encompassed in a body region of a second conductivity type on a top portion of the epitaxial layer, a gate electrode disposed in the gate trench surrounded with a first insulating film on bottom of the gate trench, and with a second insulating film on sidewalls of the gate trench; the first insulating film having a thickness greater than the second insulating film; a N-shield (Ns) region of the first conductivity type for gate oxide protection disposed directly below the gate electrode; the body region and the source region being shorted to a source metal through source contacts.

According to another aspect, in some preferred embodiments, the substrate has the first conductivity type, further comprises a Ps region of a second conductivity type for gate oxide electric-filed reduction adjoining a lower surface of the body region and being apart from the gate trench. In some other preferred embodiments, the device further comprises a super junction (SJ) structure comprising a P column region of the second conductivity type disposed above the substrate.

According to another aspect, in some preferred embodiments, the substrate has the first conductivity type and the epitaxial layer comprises a single epitaxial layer having an uniform doping concentration with a resistivity R, the SiC power device further comprises a buffer layer of the first conductivity type with a resistivity Rb sandwiched between the substrate and the epitaxial layer, wherein R<Rb. In some other preferred embodiments, the substrate has the second conductivity type and the epitaxial layer comprises a single epitaxial layer having an uniform doping concentration with a resistivity R, the SiC power device further comprises a buffer layer of the first conductivity type with a resistivity Rb sandwiched between the substrate and the epitaxial layer, wherein R>Rb.

According to another aspect, in some preferred embodiments, the substrate has the second conductivity type, further comprises a buffer layer of the first conductivity type formed sandwiched between the substrate and the epitaxial layer, and a plurality of heavily doped regions of the first conductivity type in the substrate to form a plurality of alternating P+ and N+ regions in the substrate.

According to another aspect, the present invention also features a SiC power device further comprising a current spreading region of the first conductivity type surrounding at least sidewalls of the gate trench in the active area, wherein the current spreading region has a higher doping concentration than the epitaxial layer.

According to another aspect, in some preferred embodiment, the P column region of the SJ structure is formed by multiple epi method. In some other preferred embodiment, the P column region of the SJ structure is formed by opening a deep trench filled up with an epitaxial layer of the second conductivity type.

According to another aspect, the invention also features a SiC power device formed in an epitaxial layer of a first conductivity type on a substrate of the first conductivity type, further comprising: a plurality of gate trenches surrounded by source regions of the first conductivity type encompassed in body regions of a second conductivity type on a top portion of the epitaxial layer, each of the gate trenches being filled with a gate electrode and a shielded gate electrode, wherein the shielded gate electrode being insulated from the epitaxial layer by a first insulating film, the gate electrode being insulated from the epitaxial layer by a gate oxide, the shielded gate electrode and the gate electrode being insulated from each other by an (inter-polysilicon oxide) IPO film, the gate oxide being formed along sidewalls in the upper portion of the gate trenches and having a less thickness than the first insulating film. An Ns region of the first conductivity type for gate oxide protection is disposed directly below the gate electrode; a Ps region of the second conductivity type for gate oxide electric-field reduction is formed adjoining a lower surface of the body region and being apart from the gate trench. In some other preferred embodiments, the device further comprises a SJ structure comprising a P column region of the second conductivity type disposed above the substrate.

According to another aspect, in some preferred embodiments, within each of the gate trenches, the shielded gate electrode is disposed in a lower portion and the gate electrode is disposed in an upper portion. In some other preferred embodiments, within each of the gate trenches, the shielded gate electrode is disposed in the middle and the gate electrode is a pair of split gate electrodes disposed surrounding an upper portion of the shielded gate electrode, and the second insulating film formed during growing the gate oxide is covering on the upper portion of the shielded gate electrode.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1 is a cross-sectional view of a conventional SiC semiconductor device having a trench gate vertical double diffused MOSFET.

FIGS. 2A-2C are cross-sectional views of semiconductor devices of a prior art (U.S. Pat. No. 9,923,066 B2).

FIG. 3A is a cross-sectional view of a preferred embodiment according to the present invention.

FIG. 3B is a cross-sectional view of another preferred embodiment according to the present invention.

FIG. 3C is a cross-sectional view of another preferred embodiment according to the present invention.

FIG. 4A is a cross-sectional view of another preferred embodiment according to the present invention.

FIG. 4B is a cross-sectional view of another preferred embodiment according to the present invention.

FIG. 5A is a cross-sectional view of another preferred embodiment according to the present invention.

FIG. 5B is a cross-sectional view of another preferred embodiment according to the present invention.

FIG. 6A is a cross-sectional view of another preferred embodiment according to the present invention.

FIG. 6B is a cross-sectional view of another preferred embodiment according to the present invention.

FIG. 6C is a cross-sectional view of another preferred embodiment according to the present invention.

FIG. 7A is a cross-sectional view showing another preferred embodiment according to the present invention, wherein the doping concentration variations of the N type epitaxial layer as grown are depicted along the vertical direction.

FIG. 7B is a cross-sectional view showing another preferred embodiment according to the present invention, wherein the doping concentration variations of the N type epitaxial layer as grown are depicted along the vertical direction.

FIG. 8A is a cross-sectional view showing another preferred embodiment according to the present invention, wherein the doping concentration variations of the N type epitaxial layer as grown are depicted along the vertical direction.

FIG. 8B is a cross-sectional view showing another preferred embodiment according to the present invention, wherein the doping concentration variations of the N type epitaxial layer as grown are depicted along the vertical direction.

FIG. 9A is a cross-sectional view showing another preferred embodiment according to the present invention, wherein the doping concentration variations of the N type epitaxial layer as grown are depicted along the vertical direction.

FIG. 9B is a cross-sectional view showing another preferred embodiment according to the present invention, wherein the doping concentration variations of the N type epitaxial layer as grown are depicted along the vertical direction.

FIG. 9C is a cross-sectional view showing another preferred embodiment according to the present invention, wherein the doping concentration variations of the N type epitaxial layer as grown are depicted along the vertical direction.

FIG. 9D is a cross-sectional view showing another preferred embodiment according to the present invention, wherein the doping concentration variations of the N type epitaxial layer as grown are depicted along the vertical direction.

FIG. 10A is a cross-sectional view of another preferred embodiment according to the present invention.

FIG. 10B is a cross-sectional view of another preferred embodiment according to the present invention.

FIG. 11A is a cross-sectional view of another preferred embodiment according to the present invention.

FIG. 11B is a cross-sectional view of another preferred embodiment according to the present invention.

FIG. 11C is a cross-sectional view of another preferred embodiment according to the present invention.

FIG. 11D is a cross-sectional view of another preferred embodiment according to the present invention.

FIG. 12A is a cross-sectional view of another preferred embodiment according to the present invention.

FIG. 12B is a cross-sectional view of another preferred embodiment according to the present invention.

FIG. 13A is a cross-sectional view of another preferred embodiment according to the present invention.

FIG. 13B is a cross-sectional view of another preferred embodiment according to the present invention.

FIG. 14A is a cross-sectional view of another preferred embodiment according to the present invention.

FIG. 14B is a cross-sectional view of another preferred embodiment according to the present invention.

FIG. 15A is a cross-sectional view of another preferred embodiment according to the present invention.

FIG. 15B is a cross-sectional view of another preferred embodiment according to the present invention.

FIG. 16A is a cross-sectional view of another preferred embodiment according to the present invention.

FIG. 16B is a cross-sectional view of another preferred embodiment according to the present invention.

FIG. 17A is a cross-sectional view of another preferred embodiment according to the present invention.

FIG. 17B is a cross-sectional view of another preferred embodiment according to the present invention.

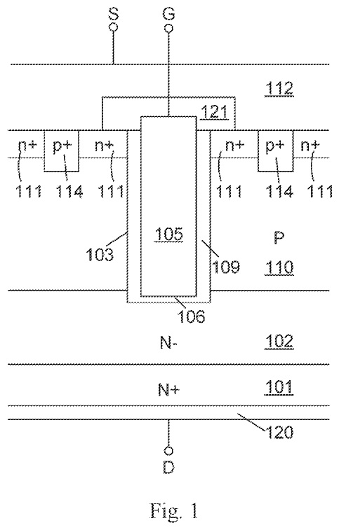

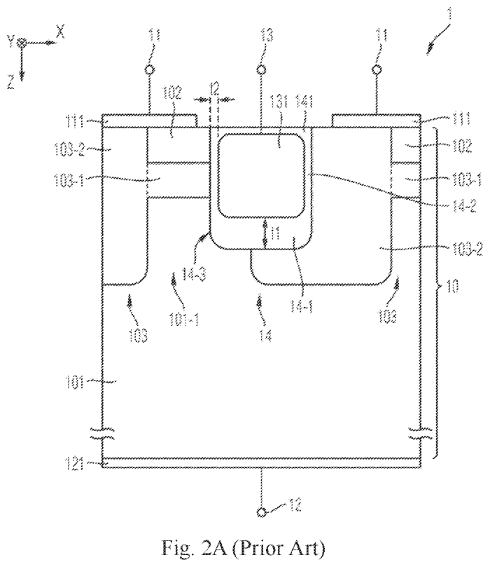

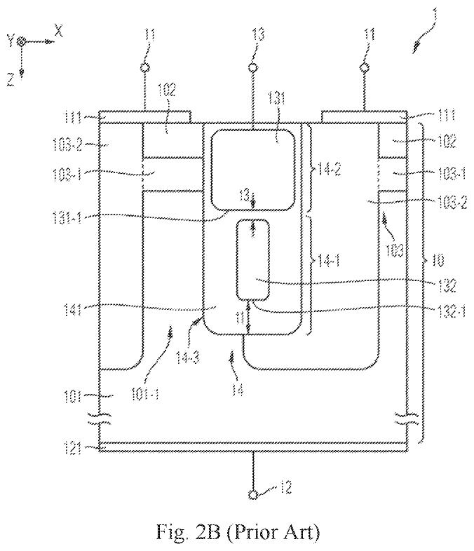

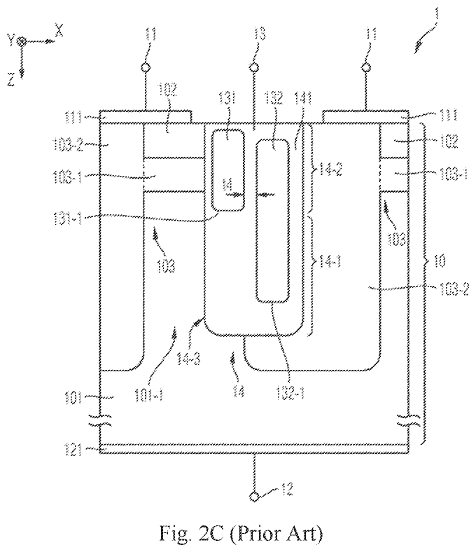

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

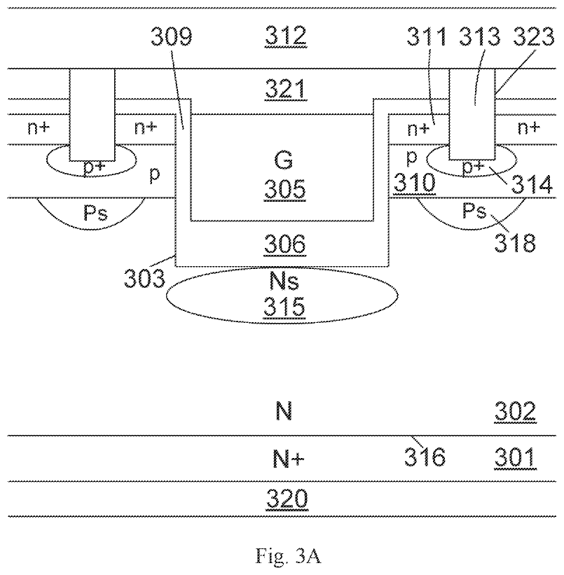

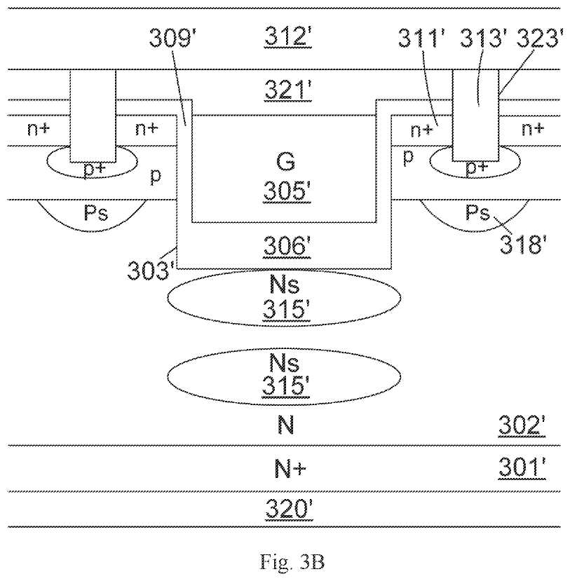

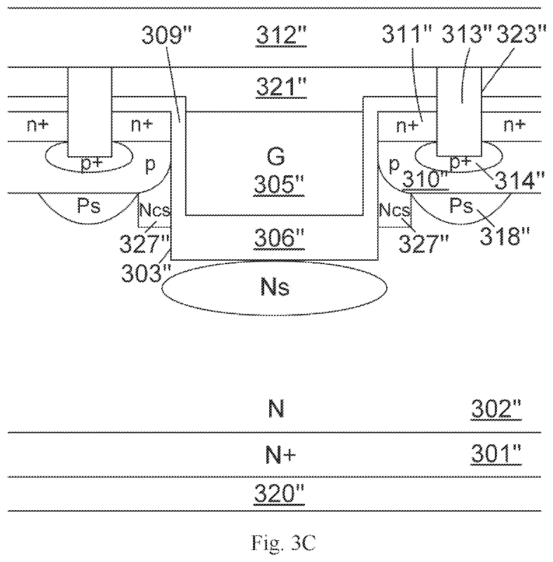

Please refer to FIG. 3A for a preferred embodiment of this invention with new and improved device structure. A SiC power device comprising a trench MOSFET formed on an N+ type SiC substrate 301 with a less doped N type SiC epitaxial layer 302 extending thereon, wherein the N+ substrate 301 is coated with a back metal 320 of Ti/Ni/Ag on rear side as a drain metal. Inside the N type epitaxial layer 302, a plurality of gate trenches 303 are formed vertically downward from a top surface of the N type epitaxial layer 302 and not reaching the interface 316 between the N type epitaxial layer 302 and the N+ substrate 301. A gate electrode 305 is disposed in an upper portion of the gate trenches 303 and surrounded with a thick bottom oxide as the first insulating film 306 on a bottom of the gate trenches 303, and with a second insulating film 309 on sidewalls of the gate trenches 303, wherein the second insulating film 309 has a less thickness than the first insulating film 306. Between every two adjacent gate trenches 303, a p body region 310 with n+ source regions 311 thereon is extending near a top surface of the N type epitaxial layer 302 and surrounding the gate electrode 305 padded by the second insulating film 309. An interlayer dielectric film 321 is stacked on the epitaxial layer 302, and the source metal 312 is formed onto the interlayer dielectric film 321. The p body regions 310, the n+ source regions 311 are further shorted to a source metal 312 comprising Ti/TiN/AI alloys through a plurality of trenched contacts 323 filled with contact plugs 313 comprising Ti/TiN alloys and surrounded by p+ heavily doped regions 314 around bottoms underneath the n+ source regions 311. An N-shield zone 315 (Ns, as illustrated) for gate oxide protection is disposed below the gate electrode 305 in the N type epitaxial layer 302, and a doping concentration of the N-shield zone 315 is higher than that of the N type epitaxial layer 302. According to the invention, a P-shield zone (Ps, as illustrated) 318 for gate oxide electric-field reduction is formed adjoining a lower surface of the body region 310 and being apart from the gate trenches 303.

Please refer to FIG. 3B for another preferred embodiment of this invention with new and improved device structure. The SiC power device has a similar structure to FIG. 3A, except that in the present invention, two N-shield zones 315′ (Ns, as illustrated) for gate oxide protection are disposed below the gate electrode 305′ (G, as illustrated) in the N type epitaxial layer 302′ with a doping concentration higher than that of the N type epitaxial layer 302′.

Please refer to FIG. 3C for another preferred embodiment of this invention with new and improved device structure. The SiC power device has a similar structure to FIG. 3A, except that in the present structure, a current spreading layer 327″ (Ncs, as illustrated) of the first conductivity type is encompassed in an upper portion of the N type epitaxial layer 302″ and below the p body region 310″ and surrounds at least sidewalls of the gate electrode 305″. The Ncs region 327″ is introduced to avoid formation of a pinching off current path between the Ps region 318″ and the gate trench 303″, wherein the Ncs region 327″ has a higher doping concentration than that of the N type epitaxial layer 302″ for on-resistance reduction.

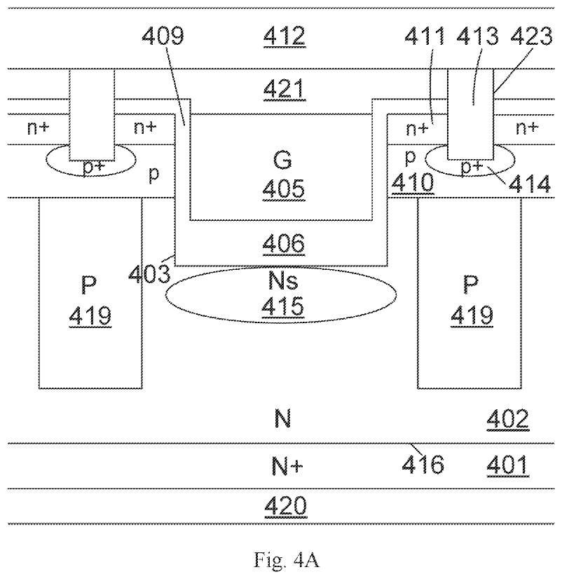

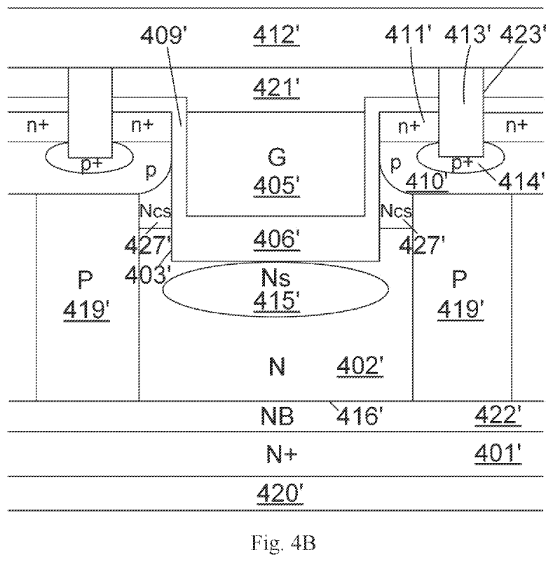

Please refer to FIG. 4A for another preferred embodiment of this invention with new and improved device structure. The SiC power device has a similar structure to FIG. 3A, except that the P-shield zones adjoining lower surfaces of the body regions in FIG. 3A don't exist in the present structure, and P column regions 419 are introduced into the N type epitaxial layer 402 to form a SJ region, comprising a plurality of alternating P column regions 419 and N type epitaxial layer 402 above the N+ substrate 401. The P column regions 419 can be easily formed below the p body regions 410 and above the bottom surface 416 of the N type epitaxial layer 402 by multiple epi method or by opening a deep trench filled up with an epitaxial layer of the second conductivity type method. The trenched source contacts 423 in the present structure are filled with contact plugs 413 comprising Ti/TiN layers while the source metal 412 comprising Ti/TiN/Al Alloys.

Please refer to FIG. 4B for another preferred embodiment of this invention with an new and improved device structure. The SiC power device has a similar structure to FIG. 4A, except that the invention in FIG. 4B further comprises a N buffer layer 422′ (NB, as illustrated) with a resistivity Rb sandwiched between the N+ substrate 401′ and the N type epitaxial layer 402′, the N type epitaxial layer 402′ comprises a single epitaxial layer having an uniform doping concentration with a resistivity R, wherein R<Rb. Besides, the P column regions 419′ in the present invention can be easily formed below the p body regions 410′ and touch to the bottom surface 416′ of the N type epitaxial layer 402′ by multiple epi method or by opening a deep trench filled up with an epitaxial layer of the second conductivity type method. Moreover, a current spreading layer 427′ (Ncs, as illustrated) of the first conductivity type is encompassed in an upper portion of the epitaxial layer and surrounds at least sidewalls of the gate electrode 405′ below the p body region 410′, wherein the Ncs region 427′ has a higher doping concentration than that of the N type epitaxial layer 402′ for on-resistance reduction.

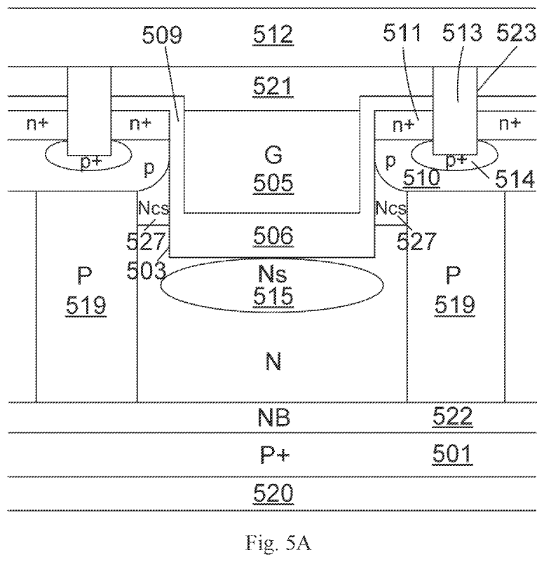

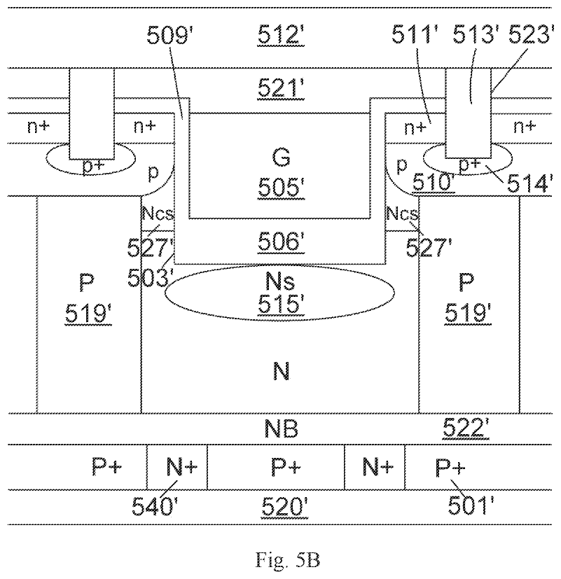

Please refer to FIG. 5A for another preferred embodiment of this invention with an new and improved device structure. The SiC power device representing an Insulating Gate Bipolar Transistor (IGBT) device has a similar structure to FIG. 4B, except for the different substrate and the R>the Rb. In this invention, the IGBT is formed on a P+ substrate 501.

Please refer to FIG. 5B for another preferred embodiment of this invention with an new and improved device structure. The SiC power device has a similar structure to FIG. 5A, except that, the IGBT in FIG. 5B further comprises a plurality of heavily doped N+ regions 540′ in the P+ substrate 501′ to form a plurality of alternating P+ and N+ regions in the substrate.

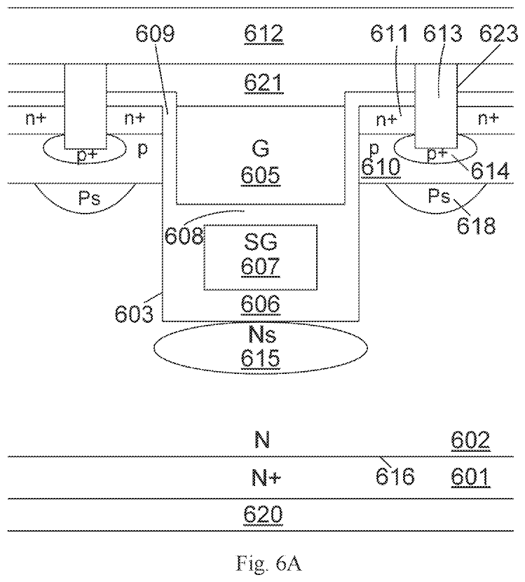

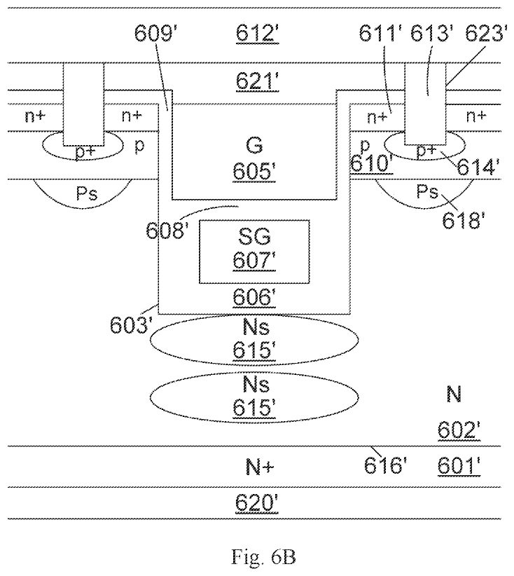

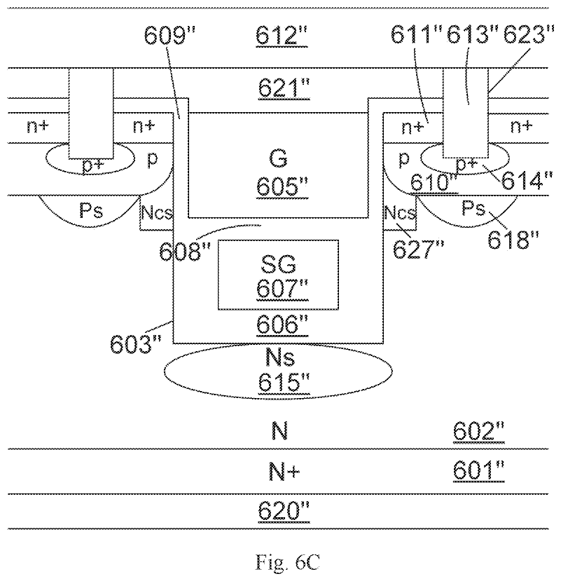

Please refer to FIG. 6A for another preferred embodiment of this invention with an new and improved device structure. The SiC SGT device has a similar structure to FIG. 3A, except for the different gate trench structure. In FIG. 6A, inside each of the gate trenches 603, a shielded gate electrode 607 (SG, as illustrated) is disposed in the lower portion and a gate electrode 605 (G, as illustrated) is disposed in the upper portion above the shielded gate electrode 607. The shielded gate electrode 607 is insulated from the adjacent epitaxial layer by a first insulating film 606, and the gate electrode 605 is insulated from the adjacent epitaxial layer by a gate oxide 609, wherein the gate oxide 609 surrounds the gate electrode 605 and has a thinner thickness than the first insulating film 606 which has an uniform thickness along trench sidewalls, meanwhile, the shielded gate electrode 607 and the gate electrode 605 are insulated from each other by an IPO film 608.

Please refer to FIG. 6B for another preferred embodiment of this invention with an new and improved device structure. The SiC SGT device has a similar structure to FIG. 6A, except that in the present invention, two N-shield zones 615′ (Ns, as illustrated) for gate oxide protection are disposed below the shielded gate electrode 607′ in the N type epitaxial layer 602′ with a doping concentration higher than that of the N type epitaxial layer 602′.

Please refer to FIG. 6C for another preferred embodiment of this invention with new and improved device structure. The SiC SGT device has a similar structure to FIG. 6A, except that in the present invention, a current spreading layer 627″ (Ncs, as illustrated) of the first conductivity type is encompassed in an upper portion of the epitaxial layer 602″ and below the p body region 610″ and surrounds at least sidewalls of the gate electrode 605″. The Ncs region 627″ is introduced to avoid formation of a pinching off current path between the Ps region 618″ and the gate trench 603″, wherein the Ncs region 627″ has a higher doping concentration than that of the N type epitaxial laver 602″ for on-resistance reduction.

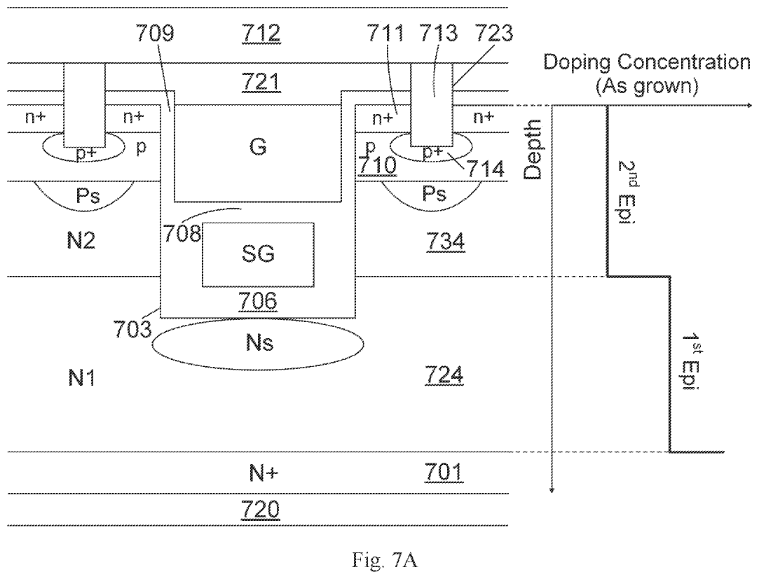

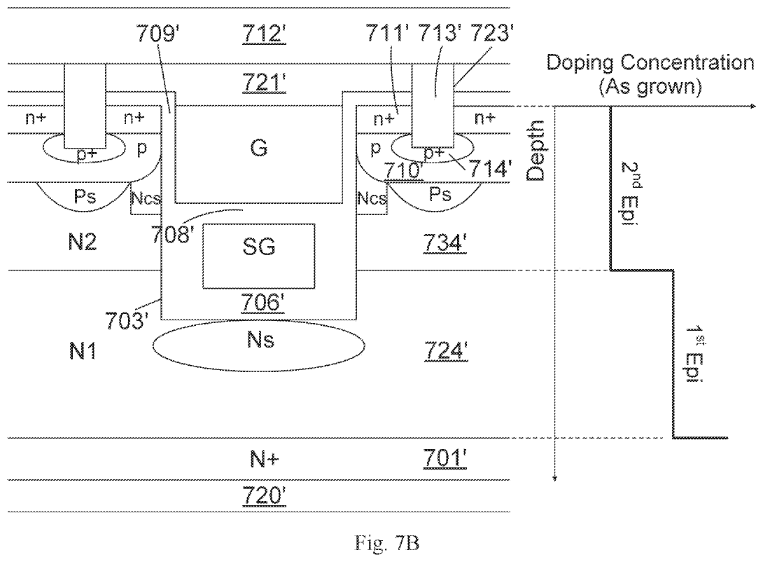

Please refer to FIG. 7A for another preferred embodiment of this invention with an new and improved device structure, wherein the doping concentration variations of the N type epitaxial layer as grown are depicted along the vertical direction. The SiC SGT device has a similar structure to FIG. 6A, except for the different epitaxial layers. In this invention, the N type epitaxial layer comprises two stepped epitaxial layers of different doping concentrations including a bottom first epitaxial layer 724 (N1, as illustrated) with a doping concentration D1 and a top second epitaxial layer 734 (N2, as illustrated) above the bottom first epitaxial layer 724 with a doping concentration D2, wherein D2<D1, to increase the breakdown voltage and lower the specific on-resistance.

Please refer to FIG. 7B for another preferred embodiment of this invention with an new and improved device structure, wherein the doping concentration variations of the N type epitaxial layer as grown are depicted along the vertical direction. The SiC SGT device has a similar structure to FIG. 6C, except for the different epitaxial layers. In this invention, the N type epitaxial layer comprises two stepped epitaxial layers of different doping concentrations including a bottom first epitaxial layer 724′ (N1, as illustrated) with a doping concentration D1 and a top second epitaxial layer 734′ (N2, as illustrated) above the bottom first epitaxial layer 724′ with a doping concentration D2, wherein D2<D1, to increase the breakdown voltage and lower the specific on-resistance.

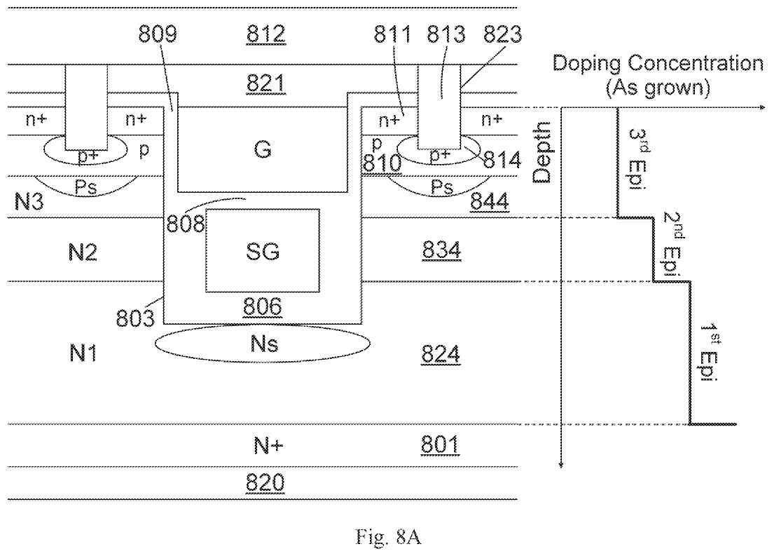

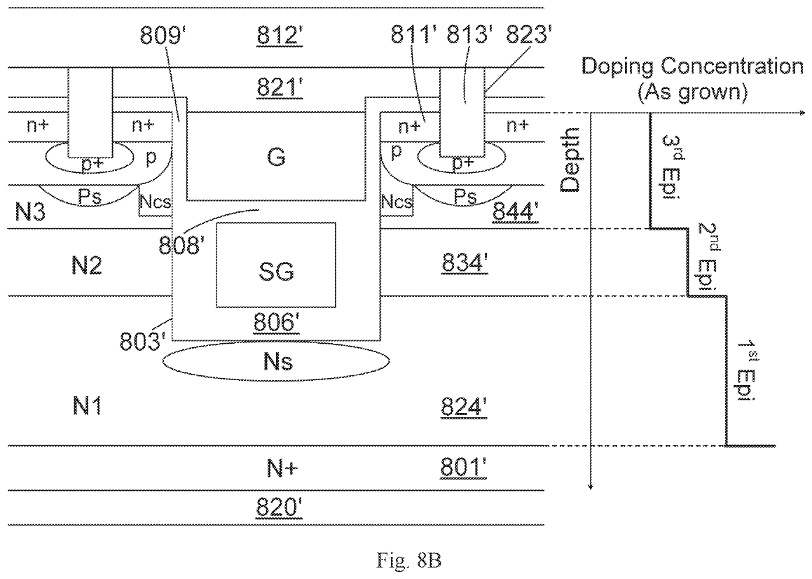

Please refer to FIG. 8A for another preferred embodiment of the present invention with an new and improved device structure, wherein the doping concentration variations of the N type epitaxial layer as grown are depicted along the vertical direction. The SiC SGT device has a similar structure to FIG. 7A, except for the different epitaxial layers. In FIG. SA, the N type epitaxial layer comprises three stepped epitaxial layers of different doping concentrations including a bottom first epitaxial layer 824 (N1, as illustrated) with a doping concentration D1, a middle second epitaxial layer 834′ (N2, as illustrated) above the first epitaxial layer 824′ with a doping concentration D2 and a top third epitaxial layer 844′ (N3, as illustrated) above the second epitaxial layer 834′ with a doping concentration D3, wherein D3<D2<D1. The D2 can be an average of D1 and D3.

Please refer to FIG. 8B for another preferred embodiment of the present invention with an new and improved device structure, wherein the doping concentration variations of the N type epitaxial layer as grown are depicted along the vertical direction. The SiC SGT device has a similar structure to FIG. 7B, except for the different epitaxial layers. In FIG. 8B, the N type epitaxial layer comprises three stepped epitaxial layers of different doping concentrations including a bottom first epitaxial layer 824′ (N1, as illustrated) with a doping concentration D1, a middle second epitaxial layer 834′ (N2, as illustrated) above the first epitaxial layer 824′ with a doping concentration D2 and a top third epitaxial layer 844′ (N3, as illustrated) above the second epitaxial layer 834′ with a doping concentration D3, wherein D3<D2<D1. The D2 can be an average of D1 and D3.

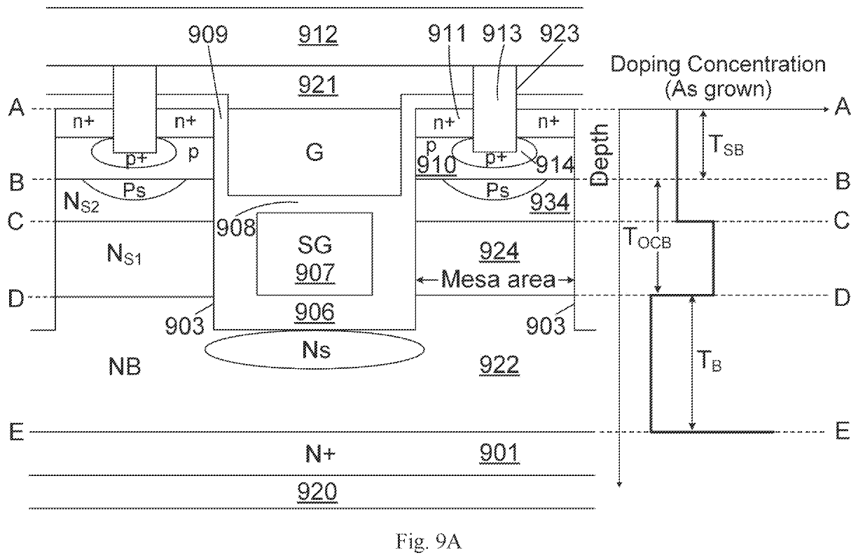

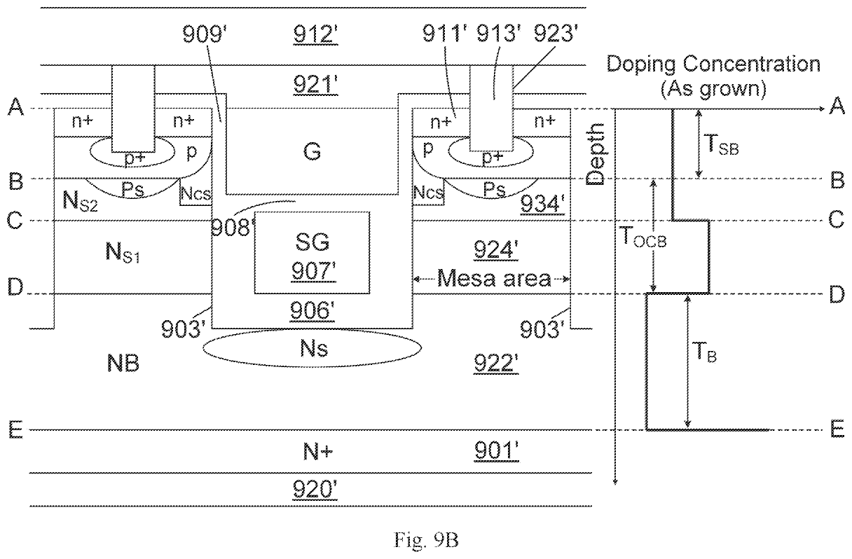

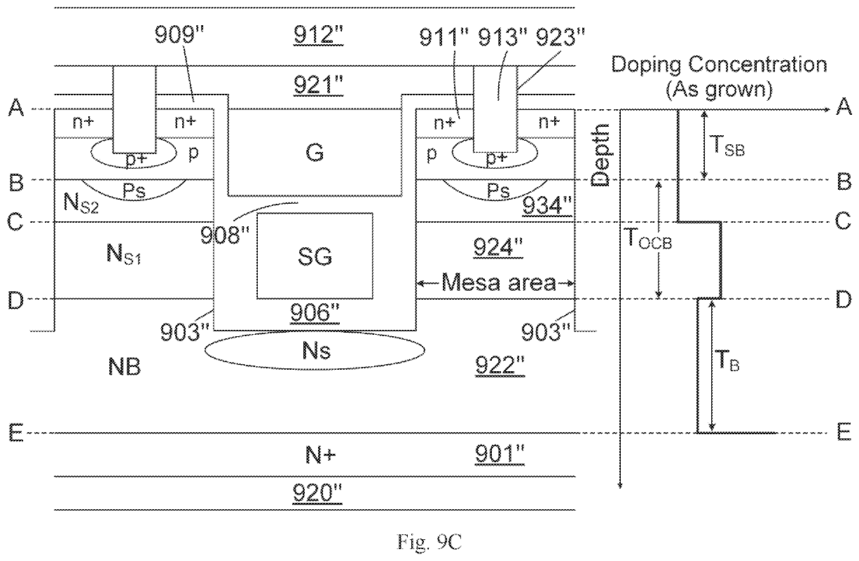

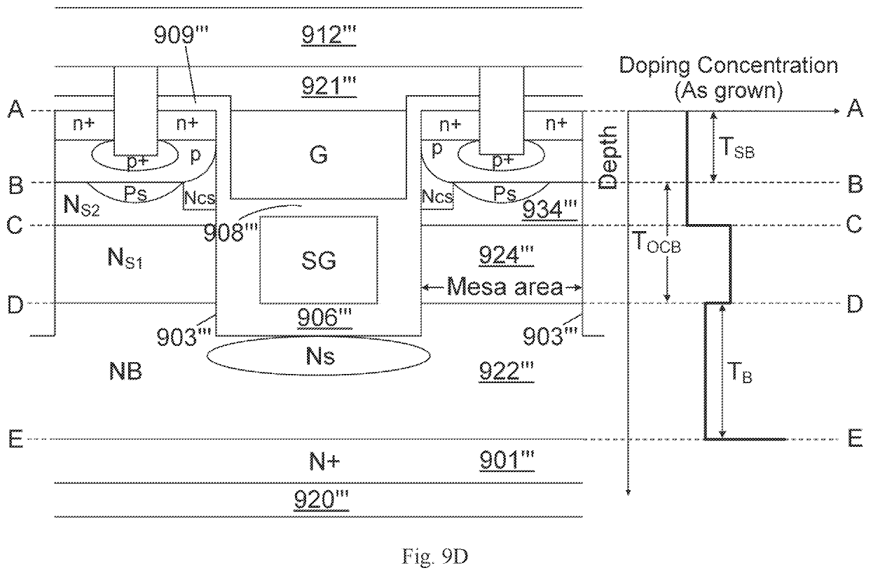

Please refer to FIG. 9A for another preferred embodiment of the present invention with an new and improved device structure, wherein the doping concentration variations of the N type epitaxial layer as grown are depicted along the vertical direction. The SiC SGT device has a similar structure to FIG. 8A, except for the epitaxial layer. In FIG. 9A, the epitaxial layer comprises a source-body (SB) region T_{SB} (between A-A and B-B lines) on a top portion of the epitaxial layer, an oxide charge balance (OCB) region T_{OCB} (between B-B and D-D lines) formed in a mesa area between the two adjacent gate trenches 903 below the body regions 910 and above a bottom of the shielded gate electrode 907 and a buffer region T_{B} formed between the N+ substrate 901 and a bottom of the shielded gate electrode 907 (between D-D and E-E lines), the epitaxial layer in the OCB region has two stepped epitaxial layers with different doping concentrations including a bottom first epitaxial layer 924 (N_{S1}, as illustrated between C-C and D-D lines) above the buffer epitaxial layer 922 (N_{B}, as illustrated between D-D and E-E lines) with a doping concentration D1, and a top second epitaxial layer 934 (N_{S2}, as illustrated between B-B and C-C lines) above the first epitaxial layer 924 with a doping concentration D2, wherein D2<D1. Moreover, the epitaxial layer in the SB region T_{SB} has a doping concentration same as that of the top second epitaxial layer 934 of the MSE layers in the OCB region T_{OCB}, and the buffer epitaxial layer 922 has a doping concentration DB lower than doping concentrations of the MSE layers in the OCB region T_{OCB}.

Please refer to FIG. 9B for another preferred embodiment of the present invention with an new and improved device structure, wherein the doping concentration variations of the N type epitaxial layer as grown are depicted along the vertical direction. The SiC SGT device has a similar structure to FIG. 8B, except for the epitaxial layer. In FIG. 9B, the epitaxial layer comprises a SB region T_{SB} (between A-A and B-B lines) on a top portion of the epitaxial Layer, an OCB region T_{OCB} (between B-B and D-D lines) formed in a mesa area between the two adjacent gate trenches 903′ below the body regions 910′ and above a bottom of the shielded gate electrode 907′ and a buffer region T_{B} formed between the N+ substrate 901′ and a bottom of the shielded gate electrode 907′ (between D-D and E-E lines), the epitaxial layer in the OCB region has two stepped epitaxial layers with different doping concentrations including a bottom first epitaxial layer 924′ (N_{S1}, as illustrated between C-C and D-D lines) above the buffer epitaxial layer 922′ (N_{B}, as illustrated between D-D and E-E lines) with a doping concentration D1, and a top second epitaxial layer 934′ (N_{S2}, as illustrated between B-B and C-C lines) above the bottom first epitaxial layer 924′ with a doping concentration D2, wherein D2<D1. Moreover, the epitaxial layer in the SB region T_{SB} has a doping concentration same as that of the top second epitaxial layer 934′ of the MSE layers in the OCB region T_{OCB}, and the buffer epitaxial layer 922′ has a doping concentration DB lower than doping concentrations of the MSE layers in the OCB region T_{OCB}.

Please refer to FIG. 9C for another preferred embodiment of the present invention with an new and improved device structure, wherein the doping concentration variations of the N type epitaxial layer as grown are depicted along the vertical direction. The SiC SGT device has a similar structure to FIG. 9A, except for the different doping concentration of the buffer region T_{B}. In FIG. 9C, the epitaxial layer in the buffer region 922″ (NB, as illustrated between D-D and E-E lines) has a doping concentration DB lower than a doping concentration D1 of the bottom first epitaxial layer 924″ (N_{S1}, as illustrated between C-C and D-D lines) in the OCB region T_{OCB} but higher than a doping concentration D2 of the top second epitaxial layer 934″ (N_{S2}, as illustrated between B-B and C-C lines) in the OCB region T_{OCB}.

Please refer to FIG. 9D for another preferred embodiment of the present invention with an new and improved device structure, wherein the doping concentration variations of the N type epitaxial layer as grown are depicted along the vertical direction. The SiC SGT device has a similar structure to FIG. 9B, except for the different doping concentration of the buffer region T_{B}. In FIG. 9D, the epitaxial layer in the buffer region 922″(NB, as illustrated between D-D and E-E lines) has a doping concentration DB lower than a doping concentration D1 of the bottom first epitaxial layer 924″ (N_{S1}, as illustrated between C-C and D-D lines) in the OCB region T_{OCB} but higher than a doping concentration D2 of the top second epitaxial layer 934″(N_{S2}, as illustrated between B-B and C-C lines) in the OCB region T_{OCB}.

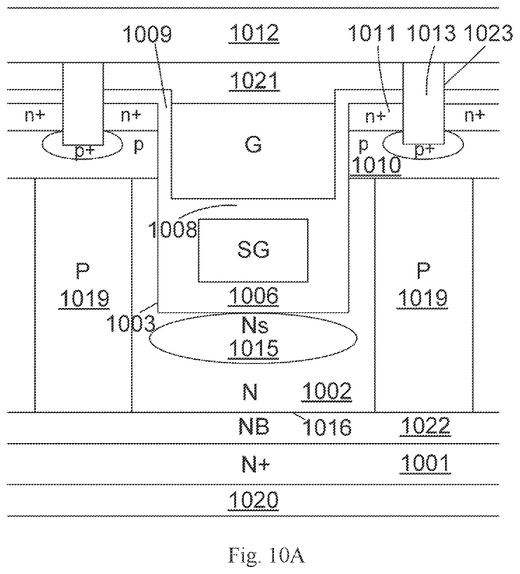

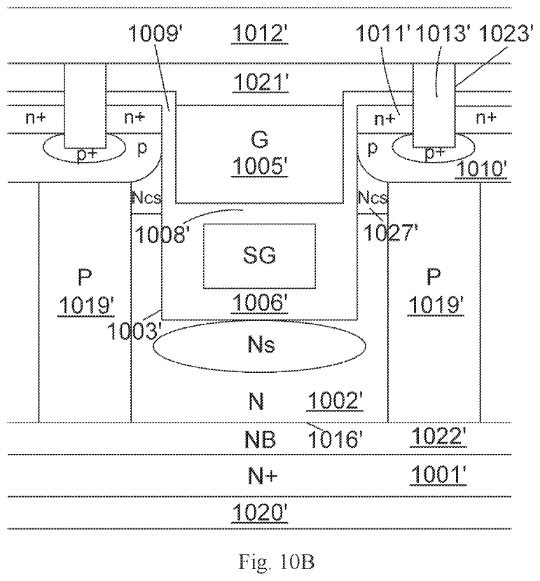

Please refer to FIG. 10A for another preferred embodiment of this invention with an new and improved device structure. The SiC SGT device has a similar structure to FIG. 6A, except that the P-shield zone adjoining lower surfaces of the body regions in FIG. 6A don't exist in the present structure, the invention in FIG. 10A further comprises a N buffer layer 1022 (NB, as illustrated) with a resistivity Rb sandwiched between the N+ substrate 1001 and the N type epitaxial layer 1002, the N type epitaxial layer 1002 comprises a single epitaxial layer having an uniform doping concentration with a resistivity R, wherein R<Rb. Besides, P column regions 1019 are introduced into the N type epitaxial layer 1002 to form a SJ region, comprising a plurality of alternating P column regions 1019 and N type epitaxial layers 1002 above the N+ substrate 1001. The P column regions 1019 can be easily formed below the p body regions 1010 and touch to the bottom surface 1016 of the N type epitaxial layer 1002 by multiple epi method or by opening a deep trench filled up with an epitaxial layer of the second conductivity type method.

Please refer to FIG. 10B for another preferred embodiment of this invention with an new and improved device structure. The SiC SGT device has a similar structure to FIG. 10A, except that in the present structure, a current spreading layer 1027′ (Ncs, as illustrated) of the first conductivity type is encompassed in an upper portion of the N type epitaxial layer 1002′ and below the p body region 1010′ and surrounds at least sidewalls of the gate electrode 1005′, and the Ncs region 1027′ has a higher doping concentration than that of the N type epitaxial layer 1002′ for on-resistance reduction.

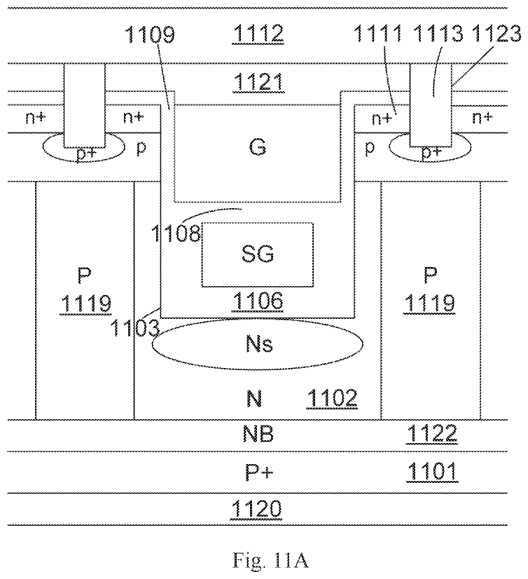

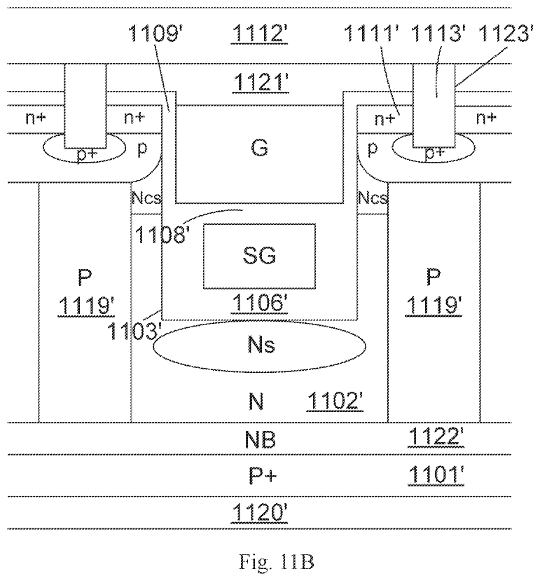

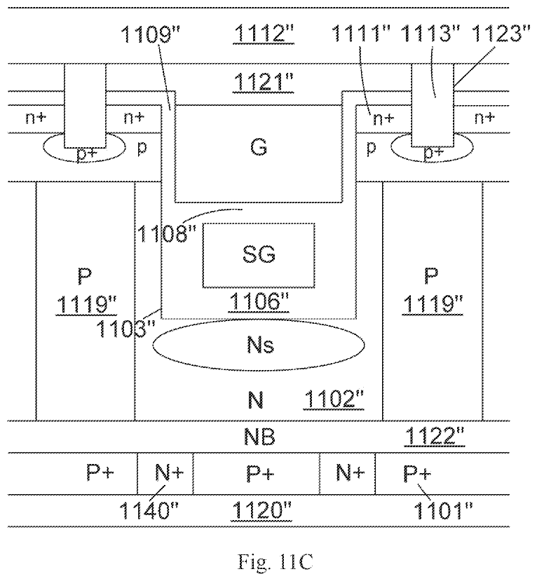

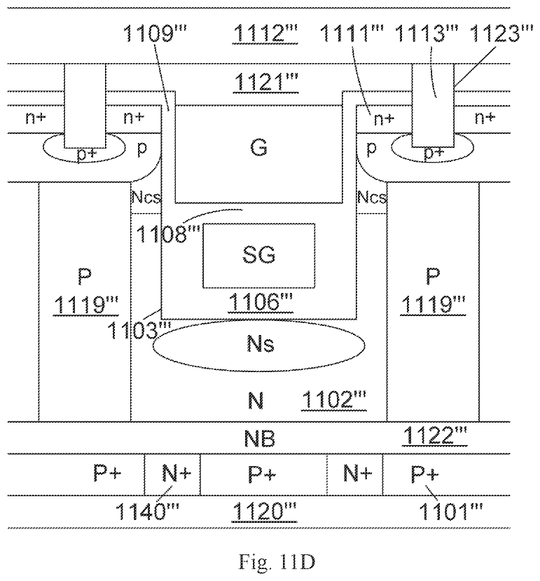

Please refer to FIG. 11A for another preferred embodiment of this invention with an new and improved device structure. The SiC SGT device representing an IGBT device has a similar structure to FIG. 10A, except for the different substrate and the R>the Rb. In this invention, the IGBT is formed onto a P+ substrate 1101.

Please refer to FIG. 11B for another preferred embodiment of this invention with an new and improved device structure. The SiC SGT device representing an IGBT device has a similar structure to FIG. 10B, except for the different substrate and the R>the Rb. In this invention, the IGBT is formed onto a P+ substrate 1101′.

Please refer to FIG. 11C for another preferred embodiment of this invention with an new and improved device structure. The SiC SGT device has a similar structure to FIG. 11A, except that, the IGBT in FIG. 11C further comprises a plurality of heavily doped N+ regions 1140″ in the P+ substrate 1101″ to form a plurality of alternating P+ and N+ regions in the substrate.

Please refer to FIG. 11D for another preferred embodiment of this invention with an new and improved device structure. The SiC SGT device has a similar structure to FIG. 11B, except that, the IGBT in FIG. 11D further comprises a plurality of heavily doped N+ regions 1140′″ in the P+ substrate 1101′″ to form a plurality of alternating P+ and N+ regions in the substrate.

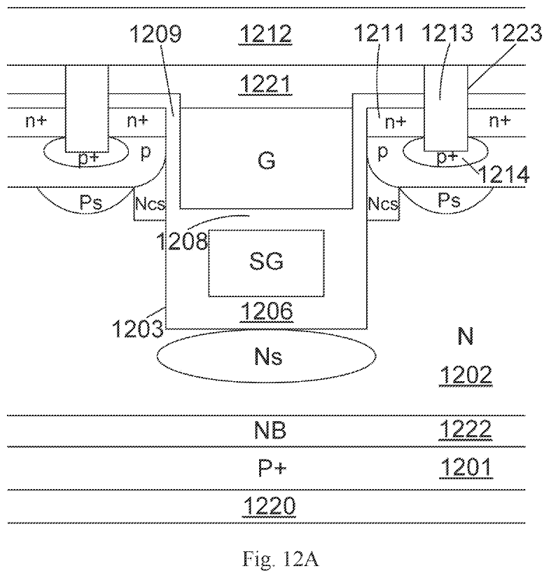

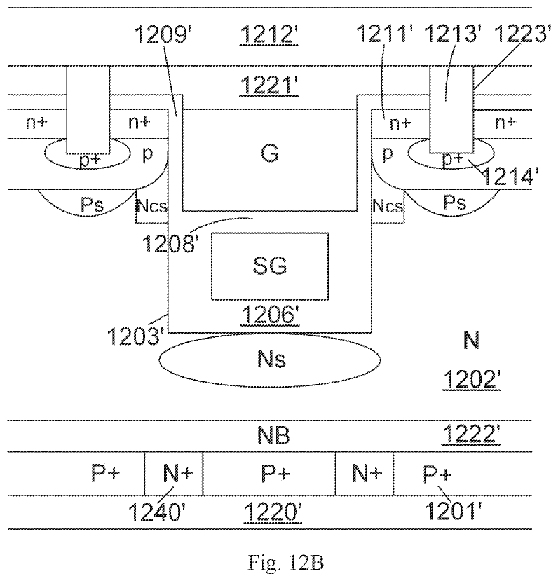

Please refer to FIG. 12A for another preferred embodiment of this invention with an new and improved device structure. The SiC SGT device representing an IGBT device has a similar structure to FIG. 6C, except for the different substrate, in this invention, the IGBT is formed onto a P+ substrate 1201. Besides, the invention in FIG. 12A further comprises a N buffer layer 1222 (NB, as illustrated) with a resistivity Rb sandwiched between the P+ substrate 1201 and the N type epitaxial layer 1202, and the N type epitaxial layer 1202 comprises a single epitaxial layer having a uniform doping concentration with a resistivity R, wherein R>Rb.

Please refer to FIG. 12B for another preferred embodiment of this invention with an new and improved device structure. The SiC SGT device has a similar structure to FIG. 12A, except that, the IGBT in FIG. 12B further comprises a plurality of heavily doped N+ regions 1240′ in the P+ substrate 1201′ to form a plurality of alternating P+ and N+ regions in the substrate.

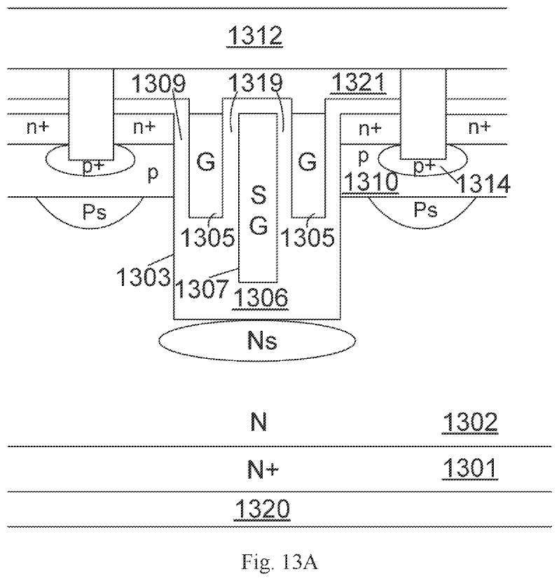

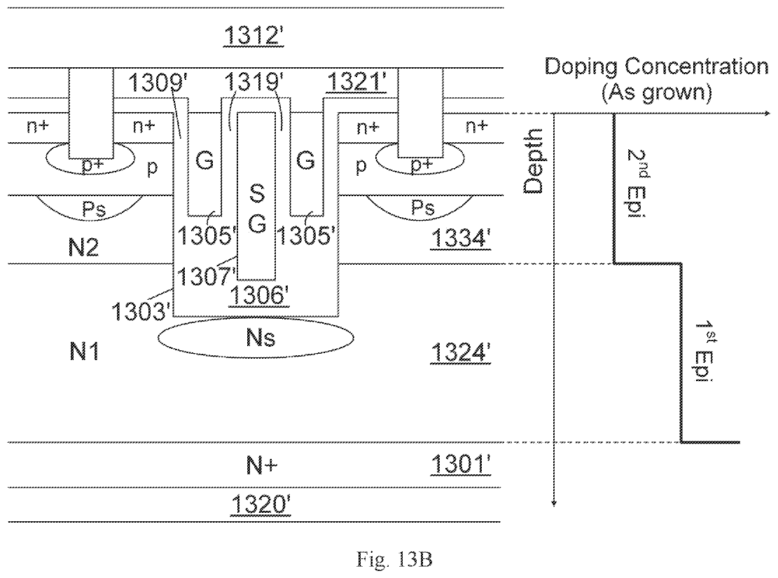

Please refer to FIG. 13A for another preferred embodiment of the present invention with an new and improved device structure. The SiC SGT device has a similar device structure to FIG. 6A, except for the different shielded gate structure in the gate trenches 1303. Inside each of the gate trenches 1303, a shielded gate electrode 1307 (SG, as illustrated) is disposed in the middle and a pair of split gate electrodes 1305 (G, as illustrated) are disposed surrounding upper portions of the shielded electrode 1307. The second insulating film 1319 isolating the shielded gate electrode 1307 and the gate electrode 1305 is covering on an upper portion of the shielded gate electrode 1307, wherein the second insulating film 1319 is formed at the same time during growing the gate oxide 1309 in the manufacturing process.

Please refer to FIG. 13B for another preferred embodiment of this invention with an new and improved device structure, wherein the doping concentration variations of the N type epitaxial layer as grown are depicted along the vertical direction. The SiC SGT device has a similar structure to FIG. 13A, except for the different epitaxial layers. In this invention, the N type epitaxial layer comprises two stepped epitaxial layers of different doping concentrations including a bottom first epitaxial layer 1324′ (N1, as illustrated) with a doping concentration D1 and a top second epitaxial layer 1334′ (N2, as illustrated) above the bottom first epitaxial layer 1324′ with a doping concentration D2, wherein D2<D1, to increase the breakdown voltage and lower the specific on-resistance.

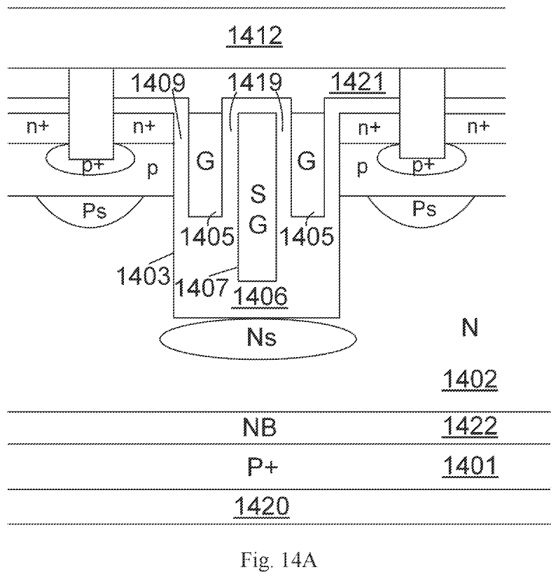

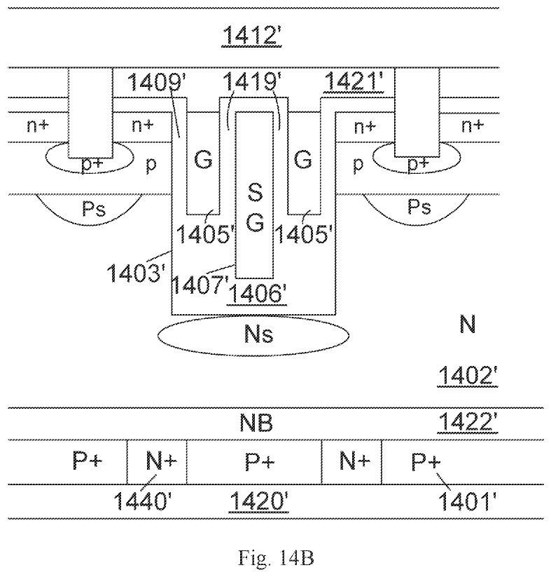

Please refer to FIG. 14A for another preferred embodiment of this invention with an new and improved device structure. The SiC SGT device representing an IGBT device has a similar structure to FIG. 13A, except for the different substrate, in this invention, the IGBT is formed onto a P+ substrate 1401. Besides, the invention in FIG. 14A further comprises a N buffer layer 1422 (N_{B}, as illustrated) with a resistivity Rb sandwiched between the P+ substrate 1401 and the N type epitaxial layer 1402, and the N type epitaxial layer 1402 comprises a single epitaxial layer having a uniform doping concentration with a resistivity R, wherein R>Rb.

Please refer to FIG. 14B for another preferred embodiment of this invention with an new and improved device structure. The SiC SGT device has a similar structure to FIG. 14A, except that, the IGBT in FIG. 14B further comprises a plurality of heavily doped N+ regions 1440′ formed in the P+ substrate 1401′ to form a plurality of alternating P+ and N+ regions in the substrate.

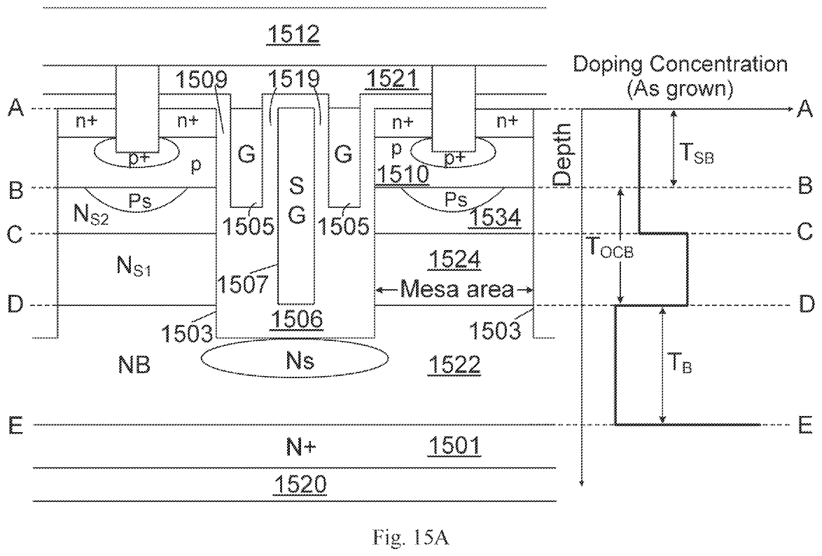

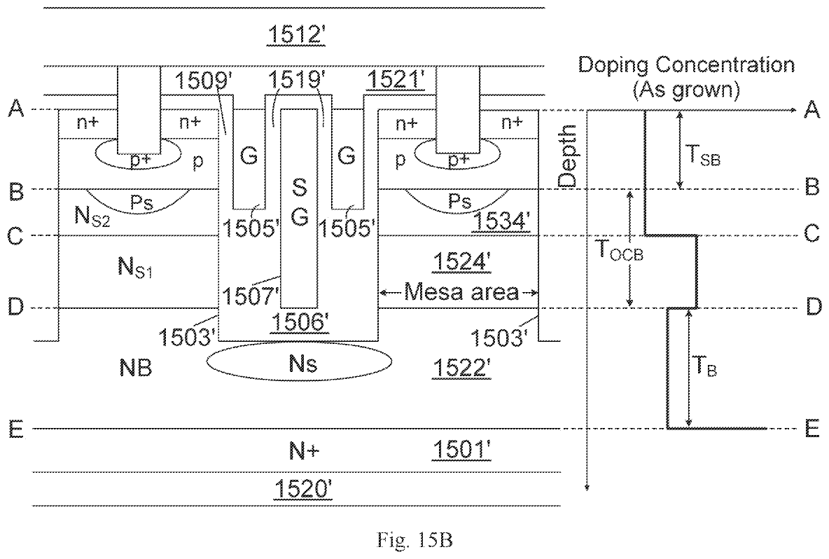

Please refer to FIG. 15A for another preferred embodiment of this invention with an new and improved device structure, wherein the doping concentration variations of the N type epitaxial layer as grown are depicted along the vertical direction. The SiC SGT device has a similar structure to FIG. 13A, except for the epitaxial layer. In FIG. 15A, the epitaxial layer comprises a SB region T_{SB} (between A-A and B-B lines) on a top portion of the epitaxial layer, an OCB region T_{OCB} (between B-B and D-D lines) formed in a mesa area between the two adjacent gate trenches 1503 below the body regions 1510 and above a bottom of the shielded gate electrode 1507 and a buffer region T_{B} formed between the N+ substrate 1501 and a bottom of the shielded gate electrode 1507 (between D-D and E-E lines), the epitaxial layer in the OCB region has two stepped epitaxial layers with different doping concentrations including a bottom first epitaxial layer 1524 (N_{S1}, as illustrated between C-C and D-D lines) above the buffer epitaxial layer 1522 (NB, as illustrated between D-D and E-E lines) with a doping concentration D1, and a top second epitaxial layer 1534 (N_{S2}, as illustrated between B-B and C-C lines) above the bottom first epitaxial layer 1524 with a doping concentration D2, wherein D2<D1. Moreover, the epitaxial layer in the SB region T_{SB} has a doping concentration same as that of the top second epitaxial layer 1534 of the MSE layers in the OCB region T_{OCB}, and the buffer epitaxial layer 1522 has a doping concentration D_{B} lower than doping concentrations of the MSE layers in the OCB region T_{OCB}.

Please refer to FIG. 15B for another preferred embodiment of the present invention with an new and improved device structure, wherein the doping concentration variations of the N type epitaxial layer as grown are depicted along the vertical direction. The SiC SGT device has a similar structure to FIG. 15A, except for the different doping concentration of the buffer region T_{B}. In FIG. 15B, the epitaxial layer in the buffer region 1522′ (NB, as illustrated between D-D and E-E lines) has a doping concentration DB lower than a doping concentration D1 of the bottom first epitaxial layer 1524′ (N_{S1}, as illustrated between C-C and D-D lines) in the OCB region T_{OCB} but higher than a doping concentration D2 of the top second epitaxial layer 1534′ (N_{S2}, as illustrated between B-B and C-C lines) in the OCB region T_{OCB}.

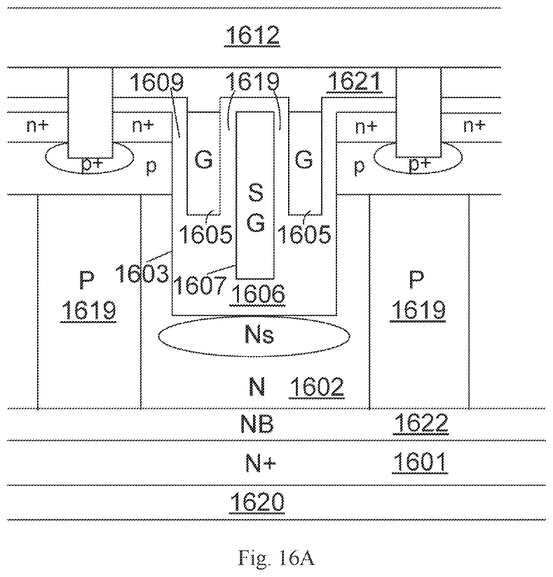

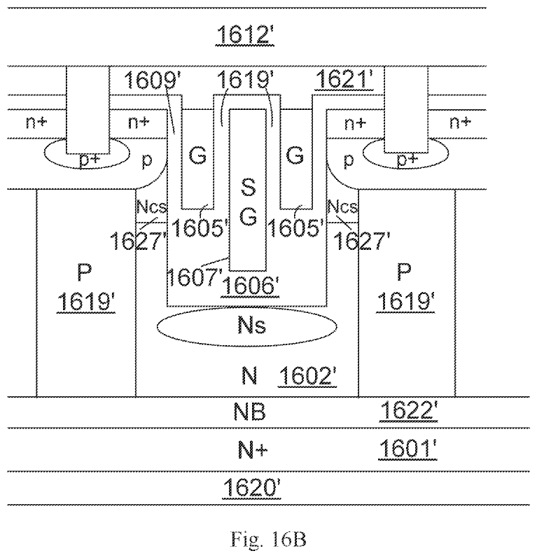

Please refer to FIG. 16A for another preferred embodiment of this invention with an new and improved device structure. The SiC SGT device has a similar device structure to FIG. 10A, except for the different shielded gate structure in the gate trenches 1603. Inside each of the gate trenches 1603, a shielded gate electrode 1607 (SG, as illustrated) is disposed in the middle and a pair of split gate electrodes 1605 (G, as illustrated) are disposed surrounding upper portions of the shielded electrode 1607. The second insulating film 1619 isolating the shielded gate electrode 1607 and the gate electrode 1605 is covering on an upper portion of the shielded gate electrode 1607, wherein the second insulating film 1619 is formed at the same time during growing the gate oxide 1609 in the manufacturing process.

Please refer to FIG. 16B for another preferred embodiment of this invention with an new and improved device structure. The SiC SGT device has a similar device structure to FIG. 16A, except that in the present structure, a current spreading layer 1627′ (Ncs, as illustrated) of the first conductivity type is encompassed in an upper portion of the epitaxial layer 1602′ and below the p body region 1610′ and surrounds at least sidewalls of the gate electrode 1605′, wherein the Ncs region 1627′ has a higher doping concentration than that of the N type epitaxial layer 1602′ for on-resistance reduction.

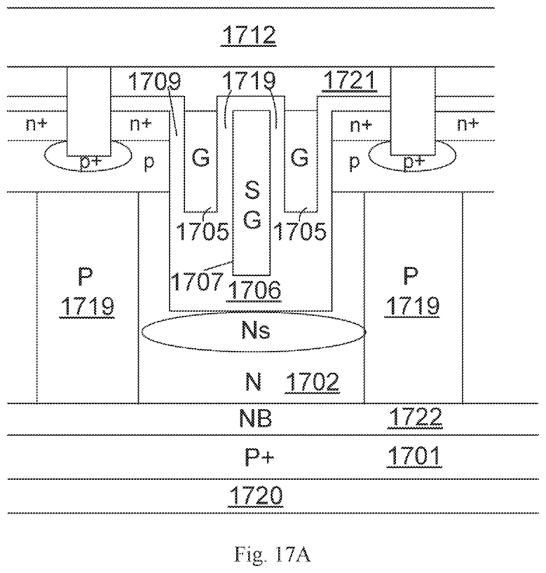

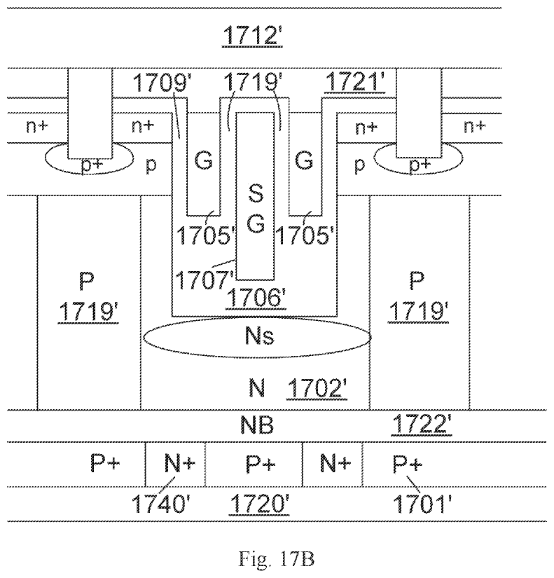

Please refer to FIG. 17A for another preferred embodiment of this invention with an new and improved device structure. The SiC SGT device representing an IGBT device has a similar structure to FIG. 16A, except for the different substrate, in this invention, the IGBT is formed onto a P+ substrate 1701.

Please refer to FIG. 17B for another preferred embodiment of this invention with an new and improved device structure. The SiC SGT device has a similar structure to FIG. 17A, except that, the IGBT in FIG. 17B further comprises a plurality of heavily doped N+ regions 1740′ formed in the P+ substrate 1801′ to form a plurality of alternating P+ and N+ regions in the substrate.

Although the present invention has been described in terms of the presently preferred embodiments, it is to be understood that such disclosure is not to be interpreted as limiting. Various alterations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A silicon carbide (SiC) power device comprising a plurality of unit cells with each unit cell in an active area comprising:
an epitaxial layer of a first conductivity type on a substrate;
at least one gate trench surrounded by a source region of said first conductivity type encompassed in a body region of a second conductivity type near a top surface of said epitaxial layer;
a gate electrode disposed in said gate trench surrounded with a first insulating film on said bottom of said gate trench, and with a second insulating film on said sidewalls of said gate trench; said first insulating film having a thickness greater than said second insulating film;
at least one N-shield zone of said first conductivity type for gate oxide protection disposed at a position deeper than said gate electrode in said epitaxial layer with a doping concentration higher than a doping concentration of said epitaxial layer;
a P-shield zone of said second conductivity type for gate oxide electric-filed reduction adjoining said lower surface of said body region and being apart from said gate trench; and
said body region and said source region being shorted to a source metal through source contacts.

2. The SiC power device of claim 1 further comprises a current spreading region of said first conductivity type surrounding at least sidewalls of said gate trench in said active area, wherein said current spreading layer has a higher doping concentration than said epitaxial layer.

3. The SiC power device of claim 1, further comprising a super junction structure comprising a P column region of said second conductivity type disposed above said substrate.

4. The SiC power device of claim 3, wherein said substrate has said first conductivity type and said epitaxial layer comprises a single epitaxial layer having an uniform doping concentration.

5. The SiC power device of claim 3, wherein said substrate has said first conductivity type and said epitaxial layer comprises a single epitaxial layer having a uniform doping concentration with a resistivity R, said SiC power device further comprises a buffer layer of said first conductivity type with a resistivity Rb sandwiched between said substrate and said epitaxial layer, wherein R<Rb.

6. The SiC power device of claim 3, wherein said substrate has said second conductivity type and said epitaxial layer comprises a single epitaxial layer having a uniform doping concentration with a resistivity R, said SiC power device further comprises a buffer layer of said first conductivity type with a resistivity Rb sandwiched between said substrate and said epitaxial layer, wherein R>Rb.

7. The SiC power device of claim 3, wherein said substrate has said second conductivity type, further comprises a buffer layer of said first conductivity type formed sandwiched between said substrate and said epitaxial layer, and a plurality of heavily doped regions of said first conductivity type in said substrate to form a plurality of alternating P+ and N+ regions in said substrate.

8. A SiC shielded gate trench (SGT) device comprising a plurality of unit cells with each unit cell in an active area comprising:
an epitaxial layer of a first conductivity type on a substrate;
at least one gate trench surrounded by a source region of said first conductivity type encompassed in a body region of a second conductivity type;
said gate trench being filled with a gate electrode and a shielded gate electrode; said shielded gate electrode being insulated from said epitaxial layer by a first insulating film, said gate electrode being insulated from said epitaxial layer by a gate oxide, said shielded gate electrode and said gate electrode being insulated from each other by an (Inter-polysilicon Oxide) IPO film, said gate oxide surrounding said gate electrode and having a less thickness than a thickness of said first insulating film;
at least one N-shield zone of said first conductivity type for gate oxide protection disposed at a position deeper than said shielded gate electrode in said epitaxial layer with a doping concentration higher than a doping concentration of said epitaxial layer;
a P-shield zone of said second conductivity type for gate oxide electric-filed reduction adjoining a lower surface of said body region and being apart from said gate trench; and
said body region and said source region being shorted to a source metal through source contacts.

9. The SiC SGT device of claim 8, wherein said epitaxial layer is a single epitaxial layer with a uniform doping concentration.

10. The SiC SGT device of claim 8, wherein said epitaxial layer has multiple stepped epitaxial (MSE) layers with different doping concentrations decreasing stepwise in a direction from said substrate to a top surface of said epitaxial layer, wherein each of said MSE layers has a uniform doping concentration as grown.

11. The SiC SGT device of claim 8, wherein said substrate has said second conductivity type.

12. The SiC SGT device of claim 8, wherein said substrate has said second conductivity type, further comprising a plurality of heavily doped regions of said first conductivity type in said substrate to form a plurality of alternating P+ and N+ regions in said substrate.

13. The SiC SGT device of claim 8, wherein said substrate has said first conductivity type, further comprising a super junction structure comprising a P column region of said second conductivity type disposed on a buffer layer of said first conductivity type with a resistivity Rb sandwiched between said substrate and said epitaxial layer, and said P column region is connected to said body region.

14. The SiC SGT device of claim 13, wherein said substrate has said first conductivity type and said epitaxial layer comprises a single epitaxial layer having a uniform doping concentration with a resistivity R, said R<said Rb.

15. The SiC SGT device of claim 13, wherein said substrate has said second conductivity type and said epitaxial layer comprises a single epitaxial layer having a uniform doping concentration with a resistivity R, said R>said Rb.

16. A SiC SGT device comprising a plurality of unit cells with each unit cell in an active area comprising:
an epitaxial layer of a first conductivity type on a substrate of said first conductivity type;
at least two gate trenches surrounded by a source region of said first conductivity type encompassed in a body region of a second conductivity type;
said gate trenches being filled with a gate electrode and a shielded gate electrode; said shielded gate electrode being insulated from said epitaxial layer by a first insulating film, said gate electrode being insulated from said epitaxial layer by a gate oxide, said shielded gate electrode and said gate electrode being insulated from each other by an (inter-polysilicon oxide) IPO film, said gate oxide surrounding said gate electrode and having a less thickness than a thickness of said first insulating film;
at least one N-shield zone of said first conductivity type for gate oxide protection disposed at a position deeper than said shielded gate electrode in said epitaxial layer with a doping concentration higher than a doping concentration of said epitaxial layer;
a P-shield zone of said second conductivity type for gate oxide electric-filed reduction adjoining lower surface of said body region and being apart from said gate trench; and
said epitaxial layer further an oxide charge balance (OCB) region and a buffer region;
said OCB region of said first conductivity type formed in a mesa area between two adjacent said gate trenches below said body region and above a bottom of said shielded gate electrode;
said buffer region of said first conductivity in said epitaxial layer formed between said substrate and said OCB region; and
said epitaxial layer in said OCB region has MSE layers with different doping concentrations decreasing stepwise in a direction from a bottom of said shielded gate electrode to said body region along sidewalls of said gate trench, wherein each of said MSE layers has a uniform doping concentration as grown.

17. The SiC SGT device of claim 16, wherein said epitaxial layer in said buffer region has a doping concentration lower than doping concentrations of said MSE layers in said OCB region.

18. The SiC SGT device of claim 16, wherein said epitaxial layer in said OCB region comprises at least two stepped epitaxial layers of different doping concentrations including a bottom epitaxial layer with a doping concentration D1 and a top epitaxial layer above said bottom epitaxial layer with a doping concentration D2, wherein said D2<said D1, and said buffer region having a doping concentration DB, wherein said D2<said DB<said D1.

19. The SiC SGT device of claim 16, further comprising a current spreading region of said first conductivity type surrounding at least sidewalls of said gate electrode below said body region, wherein said current spreading layer has a doping concentration higher than doping concentrations of said MSE layers in said OCB region.
